(19) United States
(12) Patent Application Publication
(10) Pub. No.: US 2005/0280987 A1
(43) Pub. Date: Dec. 22, 2005

(54) Phase change materials as a heat sink for computers

(76) Inventors: Benjamin J. Kwitek, Canon City, CO (US); Tsuyoshi Taira, Los Altos Hills, CA (US); Monte C. Magill, Greeley, CO (US)

Correspondence Address: WELSH & FLAXMAN LLC, 2000 DUKE STREET, SUITE 100, ALEXANDRIA, VA, 22314, US

(21) Appl. No.: 11/146,287

(22) Filed: Jun. 7, 2005

Related U.S. Application Data
(60) Provisional application No. 60/577,179, filed on Jun. 7, 2004.

(51) Int. Cl. H05K 7/20

(52) U.S. Cl. 361/687; 361/710

(57) ABSTRACT

An electronic device includes a housing in which electronic components are stored. A heat sink is positioned adjacent the housing, wherein the heat sink is composed of a phase change material.

### CROSS REFERENCE TO RELATED APPLICATIONS

This application is based upon U.S. Provisional Patent Application Ser. No. 60/577,179, filed Jun. 7, 2004, entitled “PHASE CHANGE MATERIALS AS A HEAT SINK FOR COMPUTERS”.

### BACKGROUND OF THE INVENTION

1. Field of the Invention

This invention relates to heat control in computer and electronic devices. More particularly, the invention relates to the use of phase change materials as heat sinks in the manufacture of computer devices. This invention also relates to the use of phase change materials as a method and system to control external temperatures of computer and electronic devices.

2. Description of the Prior Art

As those skilled in the art of developing faster and more robust computer devices will readily appreciate, temperature maintenance is a major problem confronting future development of faster and more powerful computing devices. As the density, power and speed of internal components utilized in computer devices has increased to produce incredibly powerful and small computing devices, the associated heat generated by these internal components has similarly increased. The problems associated with developing heat within internal components and how to remove the heat from critical components has been continually addressed within the computer industry.

Excess heat contributes to many problems for electronic and computer engineers and designers. Heat can damage or even destroy not only the chips or processors themselves but also surrounding components and devices within the computer. Heat can also slow the performance of the chip or processor and increase its likelihood of failure. The production of heat also limits the size and power of many electronic and computer devices. Finally, heat created within computer and electronic housings also escapes out. This produces warm (or hot) outside surfaces and air drafts that make human users uncomfortable.

Current computer and electronics device manufacturers use methods such as heat sinks and heat venting to control the development of heat within computing devices and other electronic devices. Almost every personal computer, for example, has a fan to help regulate the internal temperature of the machine. Although these methods are helpful, they are often not enough to counter the heat produced by today's electronic or computer devices. This problem is especially salient in small electronic and computing devices. Laptop, or notebook, computers are a prime example. These devices offer a small and thin housing in which all electronic components are packed. As the heat generating components are designed into smaller spaces, the problems associated with the development of heat become more and more relevant. There is simply not enough space for large fans and heat sinks to deal with the high levels of heat generated by today's powerful electronic components. In fact, the current trend in computing is toward smaller and smaller devices, from notebook computers to PDAs to cell phones.

In addition to the operational issues relating to heat, there is also a user comfort issue relating to the development of heat in handheld electronic devices. That is, many modern electronic and computing products become warm, or even hot, to the touch when the internal electronic components are in use. This makes using a notebook computer or other electronic device uncomfortable, unhealthy and potentially dangerous at times.

With the foregoing in mind, a need continues to exist for effective ways of combating the development of heat in modern electronic and computing devices. The present invention offers an effective and reliable mechanism for combating the development of heat in electronic and computing devices.

### SUMMARY OF THE INVENTION

It is, therefore, an object of the present invention to provide an electronic device including a housing in which electronic components are stored. A heat sink is positioned adjacent the housing, wherein the heat sink is composed of a phase change material.

It is also an object of the present invention to provide an electronic device wherein the phase change material is integrated with a fabric, foam or foil.

It is another object of the present invention to provide an electronic device wherein the phase change material is integrated with a carbon composite material.

It is a further object of the present invention to provide an electronic device wherein the phase change material is contained in microcapsules composed of a wax or wax-like essence.

It is also an object of the present invention to provide an electronic device wherein the phase change material is integrated with a polymer material.

It is still another object of the present invention to provide an electronic device wherein the polymer material is a viscoelastic material.

It is a further object of the present invention to provide an electronic device wherein the phase change material begins absorbing and managing heat around 25° Celsius to 50° Celsius.

It is still a further object of the present invention to provide an electronic device wherein the phase change material begins absorbing and managing heat around 0° Celsius to 100° Celsius.

It is also an object of the present invention to provide an electronic device wherein the phase change material is attached to internal components of the electronic device.

It is also another object of the present invention to provide an electronic device wherein the phase change material is attached to a CPU of the electronic device.

It is a further object of the present invention to provide an electronic device wherein the phase change material is attached to the housing of the electronic device.

It is also an object of the present invention to provide an electronic device wherein the phase change material takes a form chosen from the group consisting of a coating, liquid, wax, gel, foam, fabric and solid layer.

It is yet a further object of the present invention to provide an electronic device wherein the electronic device is a laptop computer.

It is another object of the present invention to provide an electronic device wherein the phase change material is between approximately 0.01 mm and 2.0 mm in thickness.

It is also an object of the present invention to provide an electronic device wherein the phase change material is in thermal communication with a thermally conductive material.

Other objects and advantages of the present invention will become apparent from the following detailed description when viewed in conjunction with the accompanying drawings, which set forth certain embodiments of the invention.

### BRIEF DESCRIPTION OF THE DRAWINGS

FIG. 1 is a perspective view of a laptop computer in accordance with the present invention.

FIG. 2 is a cross sectional view of a laptop computer in accordance with a first embodiment of the present invention.

FIG. 3 is a cross sectional view of a laptop computer in accordance with a second embodiment of the present invention.

FIG. 4 is a cross sectional view of a laptop computer in accordance with a third embodiment of the present invention.

FIG. 5 is a cross sectional view of a laptop computer in accordance with a fourth embodiment of the present invention.

FIG. 6 is a cross sectional view of a laptop computer in accordance with a fifth embodiment of the present invention.

### DESCRIPTION OF THE PREFERRED EMBODIMENTS

The detailed embodiments of the present invention are disclosed herein. It should be understood, however, that the disclosed embodiments are merely exemplary of the invention, which may be embodied in various forms. Therefore, the details disclosed herein are not to be interpreted as limiting, but merely as the basis for the claims and as a basis for teaching one skilled in the art how to make and/or use the invention.

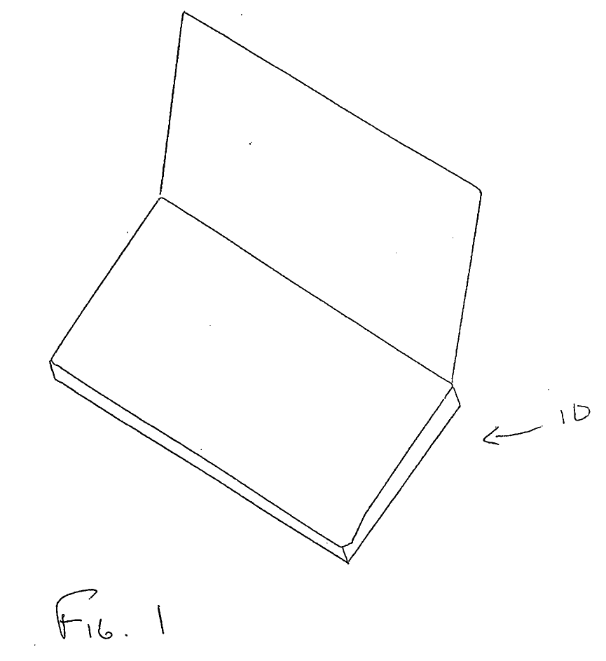

With reference to FIGS. 1, 2, 3, 4 and 5, various embodiments of a laptop computer 10, 110, 210, 310, 410 are shown incorporating phase change materials as a heat sink useful in drawing heat from critical internal components of the laptop computer. While the use of phase change materials as a heat sink in modern electronic and computing devices is disclosed herein with reference to a laptop computer, those skilled in the art will certainly appreciate the underlying concepts may applied to a wide variety of electronic and computing devices without departing from the spirit of the present invention.

In accordance with preferred embodiments as described below, the phase change material may be incorporated in a variety of forms. Specifically, the phase change material may be incorporated in and/or integrated with foam or other polymers, especially those with viscoelastic properties. The phase change material may also be incorporated into and/or integrated with a gel or liquid material. In accordance with preferred embodiments as described below, OUTLAST phase change material is utilized and functions to help in regulating the temperature of the various materials in which it is incorporated for utilization as a heat sink. It is also contemplated that multiple phase changes materials may be used in combination to produce desired results.

The example of a melting ice cube is applicable in describing the usefulness of phase change materials. As the cold cube absorbs heat, its composition or structure changes from a solid to a liquid. This process helps cool the temperature of a soft drink in the summer. The phase change materials used in accordance with the present invention perform a similar task. In this case, the phase change materials are generally contained in a polymer form. With reference to OUTLAST phase change material, the material is contained in microcapsules that contain a wax or wax-like essence. By design, the phase change materials absorb and store heat. The temperatures at which they operate and how much heat they can absorb can be modified to suit specific applications.

For use in accordance with the present invention, it is contemplated the phase change materials will begin absorbing heat around approximately 0° Celsius to 100° Celsius, and more preferably, between approximately 25° Celsius to 50° Celsius. Therefore, as the internal electronic components begin to warm and reach a threshold temperature, the phase change materials begins to work and would pull the heat away from the critical parts. These critical parts could be internal electronic components or exterior surfaces or components. The phase change materials continues to store the heat, thereby reducing the temperature of the component or device, until an engineered level. The amount of heat or energy absorption can be customized per the requirements of the specific component or device. Once the load or work of the electronic device or computer is reduced or if it was turned off and begins to cool, the absorbed energy is slowly released to moderate the temperature of the unused device. This temperature regulation process helps the components function more efficiently and more powerfully. It also helps moderate the temperatures of the device, particularly those surfaces that come into contact with human skin. In accordance with preferred embodiments, the phase change materials are bonded, coated or otherwise attached to internal components of the laptop computer. The phase change materials absorb heat from the internal components of the laptop computer and store the energy. This energy is later released to moderate the temperature of the laptop. In accordance with a preferred embodiment of the present invention, it is contemplated the phase change materials will begin absorbing heat at approximately 30° C. As the internal electronic components begin to warm, the phase change materials will begin to pull heat from the critical components.

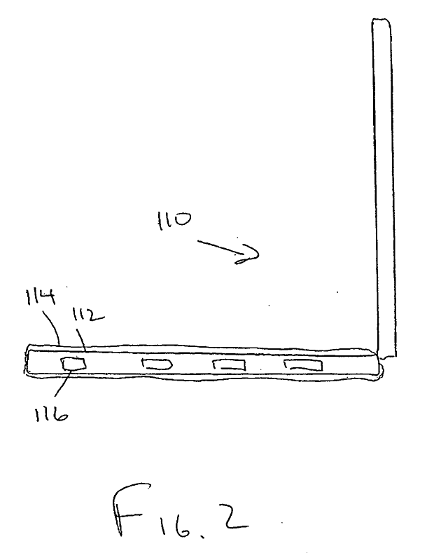

In accordance with an embodiment of the present invention and with reference to FIG. 2, the phase change material 112 is bonded, coated or otherwise attached to the housing 114 of the laptop computer. In this way, the phase change material 112 surrounds the vast majority of internal electronic components 116 drawing heat from those generating heat and protecting critical components from excessive heat. The use of metallic foils or particles in conjunction with the phase change materials might also be useful.

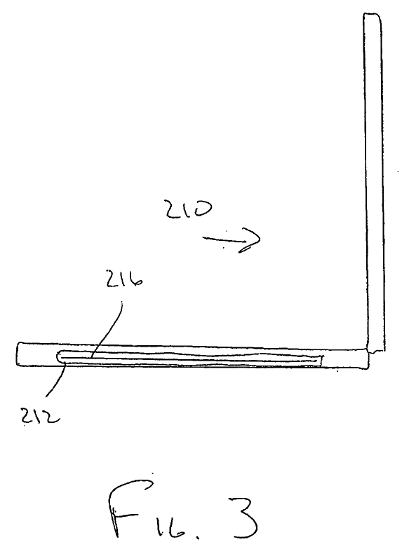

In addition, and in accordance with a further embodiment, FIG. 3 shows an embodiment where the phase change material 212 is attached directly to internal components 216 of the laptop computer 210. For example, the phase change material may be coated upon the CPU itself. A thin coating of phase change material wicks heat up and away from the silicone chip making up the CPU. The phase change material stores the heat, thereby reducing the temperature of the component or device upon which it is coated. The phase change materials may also be mixed within a liquid substrate. It is anticipated that this phase change material liquid could be passed through the electronic components much like coolant in an automobile engine. The heat is drawn from the internal component to create an ideal environment for the internal component. Once the electronic device or computer is turned off and begins to cool, the energy absorbed in the phase change material is slowly released, moderating the temperature of the unused device. This process helps components function more efficiently and more powerfully.

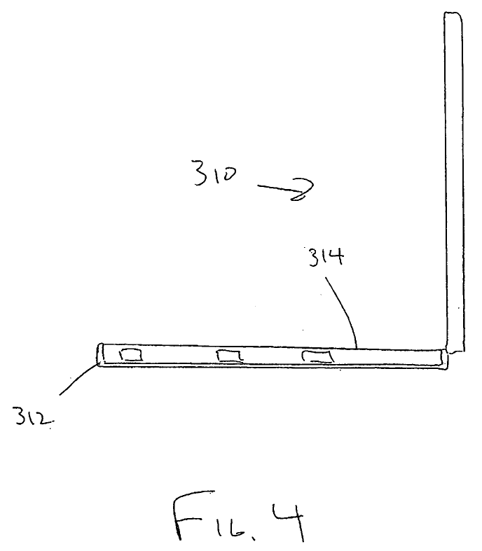

In accordance with yet a further embodiment, and with reference to FIG. 4, the phase change material 312 may take the form of a simple coating, gel, foam or fabric layer maintained within or on top of the housing 314 of the laptop computer 310.

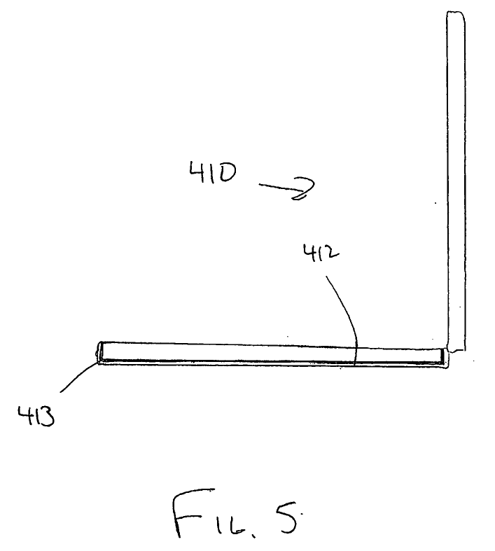

Similar to the previous embodiment, and with reference to FIG. 5, the phase change materials 412 may also be coated, integrated or otherwise attached onto advanced materials 413 such as carbon composites or carbon fiber foils or pieces. The carbon composite material may be optimized for this process. In addition to phase change materials 412, the carbon composite may include polymeric coatings or linings such as MYLAR. When combined, the carbon composite materials 413 and the phase change materials 412 help manage heat issues in and outside the laptop computer 410. In fact, the heat may be radiated in predetermined directions and then stored with phase change materials.

Regardless of the embodiment employed, the use of phase change materials within electronic and computer devices alleviates heat concerns allowing designers to develop more powerful and desirable machines without worrying about the overwhelming burden of heat slowing the devices down. In addition to the mechanical and electrical function of the machine, the use of phase change materials within a laptop computer provides human users with an immediate sensation of cool as he or she places his/her fingers, hands or arms on the device.

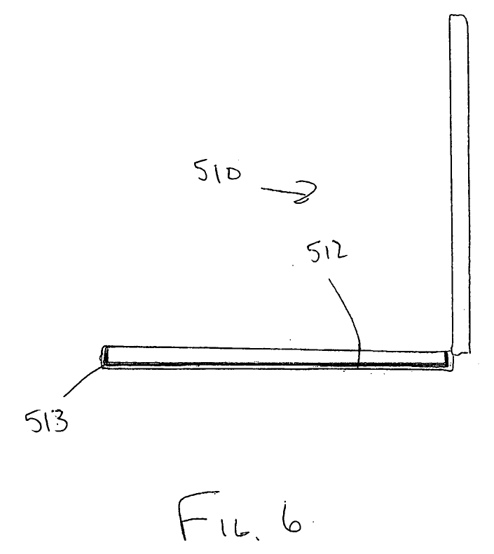

Regardless of the specific application chosen in accordance with the present invention, it is contemplated the phase change materials might also take the form of a simple coating, liquid, wax, gel, foam, fabric, foil or solid layer in addition to other variations. It is possible to incorporate the phase change materials into the component, chip, board, foil or housing surrounding these parts. Perhaps the silicon, metal, plastics or other materials could be produced with phase change material integration. For example, and with reference to FIG. 6, the phase change material may 512 be in thermal communication (e.g., via layering) with a thermally conductive foil 513 that assists in the management of heat within the laptop 510. The structure of the phase change material might also be tailored to the component or precise application. Its shape and form could be designed to maximize its heat absorption benefits. The device may also utilize a matrix of phase change materials that would activate at different temperature points or triggers. Furthermore, it is envisioned the phase change material technology would be combined with other heat reduction methods such as venting and heat sinks.

The points along the temperature curve of the device or component could be charted to determine the critical points. In this way, the very construction would alleviate heat by storing it at the proper time. The phase change materials could assist in drawing or moving heat in certain directions within the device. For example, a phase change material coated housing next to a processor would attract heat away from the processor. A soft touch or elastomeric surface could also be modified with phase change materials. This application could provide a more comfortable surface with cooler temperatures.

While the various embodiments presented above disclose the use of phase change materials within the housing, it is contemplated the phase change materials may be incorporated to external housing surfaces for the purpose of heat management.

The use of phase change materials allows for thin coatings. The phase change materials could be as thin as approximately 0.01 mm. When integrated or attached to other materials such as fabrics or foils (for example, for the purpose of using the foils as a thermally conductive layer in heat management), the total thickness would remain minimal—perhaps less than approximately 2.0 mm. In this way, these technologies are practical for installation within the small spaces of portable electronics. The phase change materials will help alleviate hot spots and provide a more comfortable computer or electronic device. With phase change materials, electronic and computer designers could make more powerful and desirable machines without the overwhelming burden of heat to slow them or their designs.

While various preferred embodiments have been shown and described, it will be understood that there is no intent to limit the invention by such disclosure, but rather, is intended to cover all modifications and alternate constructions falling within the spirit and scope of the invention.

1. An electronic device, comprising:
a housing in which electronic components are stored;
a heat sink positioned adjacent the housing, wherein the heat sink is composed of a phase change material.

2. The electronic device according to claim 1, wherein the phase change material is integrated with a fabric, foam or foil.

3. The electronic device according to claim 1, wherein the phase change material is integrated with a carbon composite material.

4. The electronic device according to claim 3, wherein the phase change material is contained in microcapsules composed of a wax or wax-like essence.

5. The electronic device according to claim 1, wherein the phase change material is integrated with a polymer material.

6. The electronic device according to claim 1, wherein the polymer material is a viscoelastic material.

7. The electronic device according to claim 1, wherein the phase change material begins absorbing and managing heat around 25° to 50° Celsius.

8. The electronic device according to claim 1, wherein the phase change material begins absorbing and managing heat around 0° Celsius to 100° Celsius

9. The electronic device according to claim 1, wherein the phase change material is attached to internal components of the electronic device.

10. The electronic device according to claim 9, wherein the phase change material is attached to a CPU of the electronic device.

11. The electronic device according to claim 1, wherein the phase change material is attached to the housing of the electronic device.

12. The electronic device according to claim 1, wherein the phase change material takes a form chosen from the group consisting of a coating, liquid, wax, gel, foam, fabric and solid layer.

13. The electronic device according to claim 1, wherein the electronic device is a laptop computer.

14. The electronic device according to claim 1, wherein the phase change material is between approximately 0.01 mm and 2.0 mm in thickness.

15. The electronic device according to claim 1, wherein the phase change material is in thermal communication with a thermally conductive material.
